(19) United States
(12) Patent Application Publication
(10) Pub. No.: US 2020/0200797 A1
(43) Pub. Date: Jun. 25, 2020

(54) INSPECTION JIG, METHOD FOR MANUFACTURING INSPECTION JIG, AND INSPECTION APPARATUS INCLUDING INSPECTION JIG

(71) Applicant: Nidec-Read Corporation, Kyoto (JP)

(72) Inventors: Hidekazu YAMAZAKI, Kyoto (JP); Norihiro OTA, Kyoto (JP)

(73) Assignee: Nidec-Read Corporation, Kyoto (JP)

(21) Appl. No.: 16/716,500

(22) Filed: Dec. 17, 2019

(30) Foreign Application Priority Data
Dec. 21, 2018 (JP) 2018-239188

(51) Int. Cl. G01R 1/067; G01R 1/04

(52) U.S. Cl. CPC G01R 1/06722; G01R 1/0408

(57) ABSTRACT

The inspection jig includes a rod-shaped probe in which one end portion is brought into press contact with an inspection target; and a plate-shaped first support having a support hole which supports the probe. The support hole includes a first taper hole portion having a diameter that increases from a side of one wall surface of the first support toward a side of a plate-thickness-direction middle portion of the first support.

### CROSS REFERENCE TO RELATED APPLICATION

This application claims the priority benefit of Japan Application No. 2018-239188, filed on Dec. 21, 2018. The entirety of the above-mentioned patent application is hereby incorporated by reference herein and made a part of this specification.

### BACKGROUND OF THE DISCLOSURE

### Technical Field

The disclosure relates to an inspection jig that is used in inspection of an inspection target, a method for manufacturing the inspection jig, and an inspection apparatus including the inspection jig.

### Related Art

Conventionally, an inspection jig is known which includes a plurality of probes having a front end which comes into contact with an inspection target, the probes being formed in a wire shape and having elasticity to be bendable, a front-side support that supports a front-side part of the probe, and a rear-side support disposed behind the front-side support via a predetermined gap (for example, see patent literature 1: Japanese Laid-Open No. 2009-47512).

The inspection jig is configured to determine that the inspection target is good or bad by measuring electrical characteristics of the inspection target, in a state that one end portion of the probe penetrating a front-side insertion hole formed in the front-side support is brought into contact with an inspected portion of a substrate, and a rear end portion of the probe supported by the rear-side support is brought into contact with an electrode of an electrode plate.

In order for the above-described probe to come into correct contact with the inspected portion, the probe needs to be stably supported by the front-side support and the rear-side support. In particular, since a large force is applied to the front-side support from the probe, it is desirable that a plate thickness of the front-side support is sufficiently increased and thereby deformation of the front-side support is suppressed and the probe is stably supported.

### SUMMARY

The probe has a very small diameter, and thus a drill having a fine diameter corresponding to the diameter of the probe needs to be used to form a probe supporting hole having a fine diameter in the front-side support. In this case, when the plate thickness of the front-side support is large, it is difficult for the drill to penetrate the front-side support.

Therefore, as illustrated in FIG. 9, for example, a lower drill hole 511 and an upper drill hole 512 are individually formed in a plurality of support plates 521 and 522, respectively, and the support plates are overlapped with each other to form a support 5 that supports a front-side part of the probe. Consequently, a probe supporting hole having a fine diameter can be formed in the support 5 having a large plate thickness T while bending or the like of the drill is inhibited. However, when the plurality of support plates 521 and 522 are overlapped with each other to configure the support 5, a positional deviation of axial centers of the lower drill hole 511 and the upper drill hole 512 may occur. Hence, when the probe is supported by the support 5, the probe is likely to be jammed in the holes.

Moreover, in order to prevent the probe from being jammed due to the occurrence of the positional deviation of the axial centers of the lower drill hole 511 and the upper drill hole 512, as illustrated in FIG. 10, for example, it is also considered to further arrange a middle drill hole 513 having a large diameter in the support plate 521 positioned at a lower side.

That is, it is also considered to perform processing of the upper drill hole 512 having a small hole on the upper support plate 522, and to individually perform processing of the lower drill hole 511 having a small diameter and the middle drill hole 513 having a large diameter on the lower support plate 521. However, in this case, it is necessary to perform hole processing three times, and there is a concern that productivity of the inspection jig cannot be improved.

The disclosure provides an inspection jig for which productivity can be improved, a method for manufacturing the inspection jig, and an inspection apparatus including the inspection jig.

An inspection jig according to an example of the disclosure includes: a rod-shaped probe in which one end portion is brought into press contact with an inspection target; and a plate-shaped first support having a support hole which supports the probe. The support hole has a first taper hole portion having a diameter that increases from a side of one wall surface of the first support toward a side of a plate-thickness-direction middle portion of the first support.

In addition, a method for manufacturing the inspection jig according to another example of the disclosure includes: a first taper hole portion forming step for forming the first taper hole portion in the first support plate; and a connecting step for overlapping and connecting the first support plate and the second support plate.

In addition, an inspection apparatus according to still another example of the disclosure includes: the above-described inspection jig; and an inspection part that is electrically connected to a rear end portion of the probe and transmits an electric signal to the rear end portion of the probe to inspect an inspection target.

### BRIEF DESCRIPTION OF THE DRAWINGS

FIG. 1 is an explanatory diagram illustrating an overall configuration of an inspection apparatus including an inspection jig according to an example of the disclosure.

FIG. 2 is a sectional view illustrating a specific configuration of an inspection jig according to a first embodiment of the disclosure.

FIG. 3 is an explanatory view illustrating a configuration of a probe supported by the inspection jig.

FIG. 4 is a sectional view illustrating a configuration of main parts of the inspection jig.

FIG. 5 is an explanatory view illustrating a forming step of a first taper hole portion.

FIG. 6 is an explanatory view illustrating a forming step of a second taper hole portion.

FIG. 7 is a sectional view illustrating a state in which an electrode plate is connected to an electrode-side support.

FIG. 8 is a sectional view illustrating an inspection state in which one end portion of the probe is brought into contact with an inspected portion.

FIG. 9 is a sectional view illustrating a first reference example of a support of the probe.

FIG. 10 is a sectional view illustrating a second reference example of the support of the probe.

FIG. 11 is a sectional view illustrating a state in which the one end portion of the probe is supported by an inspection-side support.

FIG. 12 is a sectional view illustrating a variation example of the inspection jig according to the first embodiment of the disclosure.

FIG. 13 is an explanatory view illustrating a forming step of a first taper hole portion in the variation example of the inspection jig.

FIG. 14 is an explanatory view illustrating a state in which the first taper hole portion is formed in the variation example of the inspection jig.

FIG. 15 is an explanatory view illustrating a forming step of a second taper hole portion in the variation example of the inspection jig.

FIG. 16 is a sectional view illustrating main parts of an inspection jig according to a second embodiment of the disclosure.

FIG. 17 is a sectional view illustrating main parts of an inspection jig according to a third embodiment of the disclosure.

### DESCRIPTION OF THE EMBODIMENTS

The inspection jig having such a configuration, the method for manufacturing the inspection jig, and the inspection apparatus including the inspection jig can improve the productivity of the inspection jig and the inspection apparatus.

Embodiments according to the disclosure is described below with reference to the drawings. Moreover, configurations assigned with the same reference signs in the drawings are meant to be the same configurations, and description thereof is omitted.

### First Embodiment

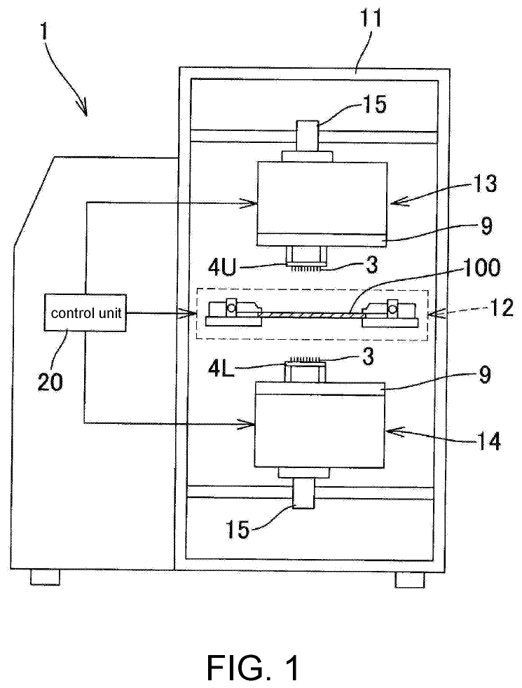

An inspection apparatus 1 illustrated in FIG. 1 includes a housing 11. An inspection-target securing device 12, a first inspection part 13, and a second inspection part 14 are arranged in an internal space of the housing 11. The inspection-target securing device 12 is configured to secure an inspection target 100 consisting of a substrate or the like at a predetermined position.

The inspection target 100 may include, for example, a glass epoxy substrate, a flexible substrate, a ceramic multi-layer wiring substrate, an electrode plate for a liquid crystal display or a plasma display, a transparent conductive plate for a touch panel or the like, and various substrates such as a package substrate for a semiconductor package or a film carrier. An inspected portion such as a wiring pattern or a solder bump is formed at the inspection target 100.

The first inspection part 13 is positioned above the inspection target 100 secured to the inspection-target securing device 12. The second inspection part 14 is positioned below the inspection target 100 secured to the inspection-target securing device 12. The first inspection part 13 and the second inspection part 14 have inspection jigs 4U and 4L, respectively, the inspection jigs inspecting a circuit pattern formed on the inspection target 100. A plurality of probes 3 are attached to the inspection jigs 4U and 4L. In addition, the first inspection part 13 and the second inspection part 14 include an inspection-part moving mechanism 15 that enables the inspection parts to appropriately move in the housing 11.

The inspection apparatus 1 includes a control unit 20 that controls operations of the inspection-target securing device 12, the first inspection part 13, the second inspection part 14, and the like. The control unit 20 is configured using a microcomputer, for example. The control unit 20 is configured to appropriately move the first inspection part 13 and the second inspection part 14, to cause the probes 3 of the inspection jigs 4U and 4L to come into contact with the inspection target 100 secured to the inspection-target securing device 12, and thereby to inspect a circuit pattern of the inspection target 100. Since the inspection jigs 4U and 4L have the same configuration, hereinafter, the inspection jigs 4U and 4L are collectively referred to as an inspection jig 4.

Moreover, the inspection apparatus 1 is not limited to a substrate inspecting apparatus that inspects a substrate and may be a semiconductor inspecting apparatus that inspects an electronic component such as a semiconductor wafer in which circuits corresponding to a plurality of semiconductor chips are formed at a semiconductor substrate such as silicon, a semiconductor chip, a chipsize package (CSP), or a semiconductor element (integrated circuit (IC)). In addition, the inspection jig 4 may be a so-called probe card that causes the plurality of probes 3 to come into contact with the semiconductor wafer so as to inspect the semiconductor wafer.

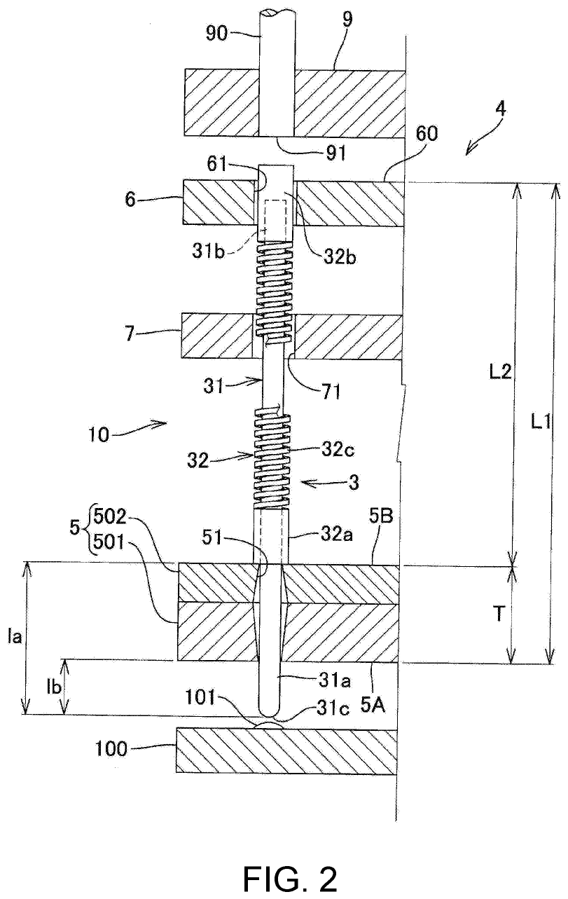

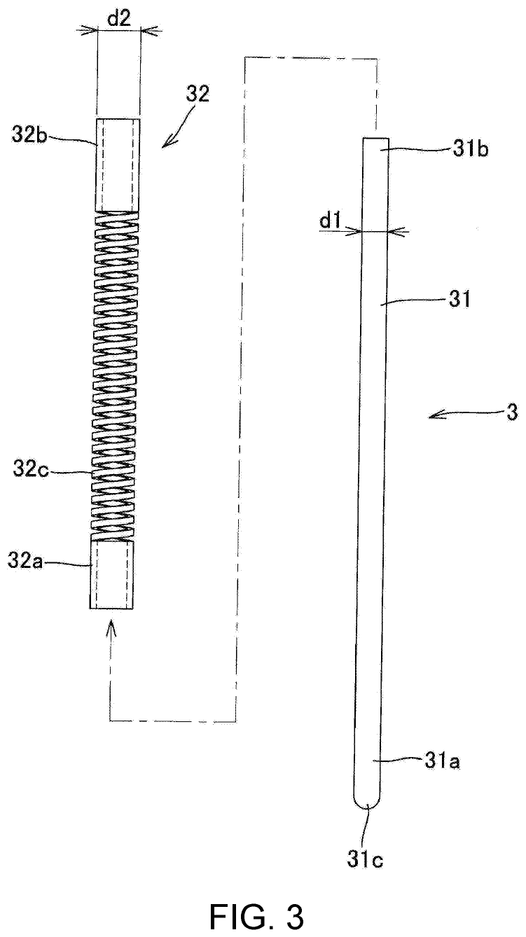

As illustrated in FIG. 2, the inspection jig 4 includes the rod-shaped probes 3 having conductivity and a support member 10 that supports the plurality of probes 3. As illustrated in FIG. 3, the probe 3 has a rod-shaped body 31 configured of a conductive member formed in a rod shape having an outer diameter d1 of about 30 μm for example, and a cylindrical body 32 configured of a conductive member which is externally fitted on the rod-shaped body 31.

A hemispheric front-end contact portion 31c brought into contact with an inspected portion 101 of the inspection target 100 is formed at one end portion 31a of the rod-shaped body 31. Moreover, the front-end contact portion 31c is not limited to the hemispherical shape and may have a tapered truncated conical shape, a conical shape, a flat surface shape, or the like.

The cylindrical body 32 has one end portion 32a having a cylindrical shape and the other end portion 32b having a cylindrical shape. In addition, a helical spring portion 32c is arranged between the one end portion 32a and the other end portion 32b of the cylindrical body 32.

A main body part of the rod-shaped body 31 is inserted into the cylindrical body 32, and the one end portion 32a of the cylindrical body 32 is fixed to the one end portion of the rod-shaped body 31 by performing a caulking process or the like. Besides, as illustrated in FIG. 2, in a state that the one end portion 31a of the rod-shaped body 31 projecting out of the cylindrical body 32 has a constant projecting length 1a, the one end portion 31a of the rod-shaped body 31 and the one end portion 32a of the cylindrical body 32 are coupled to each other. Moreover, a bulging portion having a large diameter which is arranged at the one end portion 31a of the rod-shaped body 31 may be press-fitted or the like into the one end portion 32a of the cylindrical body 32, thereby coupling the rod-shaped body 31 and the cylindrical body 32 to each other.

The other end portion 31b of the rod-shaped body 31, which is positioned at an upper side in FIG. 2, is disposed at a position entering the cylindrical body 32 by a predetermined distance from the other end portion 32b of the cylindrical body 32. An amount of the entering of the other end portion 31b of the rod-shaped body 31 is set to a value larger than an amount of deformation of the cylindrical body 32 that is compressed and elastically deformed during inspection of the inspection target 100 described later. Consequently, even when the cylindrical body 32 is compressed and deformed during the inspection of the inspection target 100, the other end portion 31b of the rod-shaped body 31 is prevented from coming into a state of projecting out of the cylindrical body 32.

The support member 10 has a first support configured of an inspection-side support 5 that is disposed to face the inspection target 100 which is positioned at a lower portion in FIG. 2. In addition, the support member 10 has a second support consisting of an electrode-side support 6 that is disposed at the upper side in FIG. 2 and a middle portion support 7 that is disposed between the inspection-side support 5 and the electrode-side support 6. The inspection-side support 5, the electrode-side support 6, and the middle portion support 7 are coupled to each other via a coupling member (not illustrated) for example, in a state of facing each other while being separated from each other by predetermined distances.

A larger force is applied to the inspection-side support 5 from the probe 3, compared with the electrode-side support 6 and the middle portion support 7. Therefore, a plate thickness of the inspection-side support 5 is set to a value larger than that of a plate thickness of the electrode-side support 6 and the middle portion support 7.

The inspection-side support 5 includes a first support plate 501 having a facing wall surface 5A facing the inspection target 100 and a second support plate 502 having an opposite wall surface 5B which is positioned at an opposite side of the facing wall surface 5A, that is, at an upper side in FIG. 2. The first support plate 501 and the second support plate 502 are adhered or welded to each other or are integrally connected to each other via a coupling bolt or the like, and thereby the inspection-side support 5 is configured.

Moreover, in the embodiment, an example in which the first support plate 501 is formed to have a plate thickness larger than that of the second support plate 502 is described; however, the plate thickness of the second support plate 502 may be larger than that of the first support plate 501. In addition, the plate thickness of the first support plate 501 may be equal to the plate thickness of the second support plate 502.

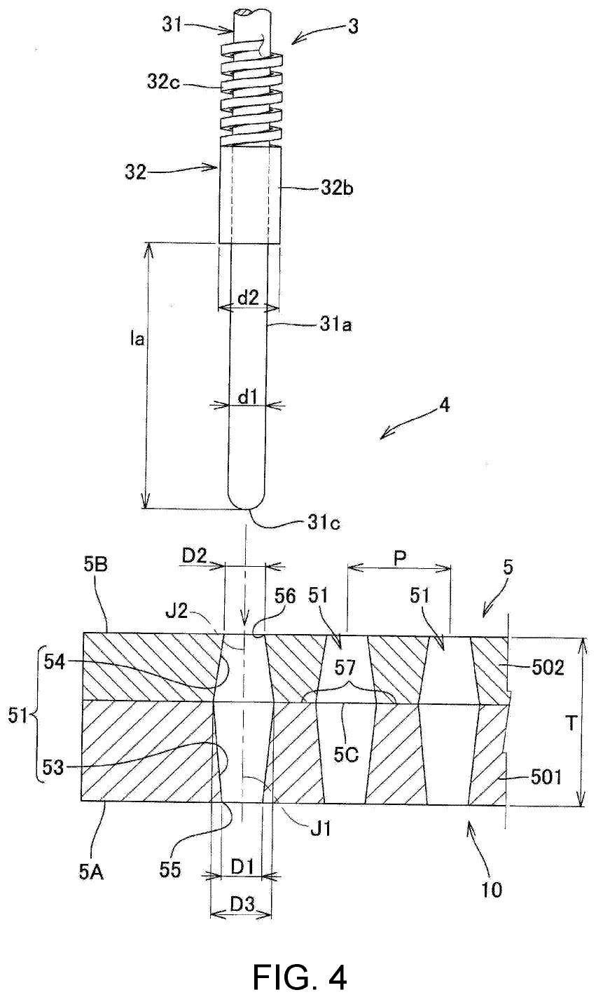

As illustrated in FIG. 4, the first support plate 501 has a first taper hole portion 53 having a diameter that increases from a side of one wall surface of the inspection-side support 5, that is, the facing wall surface 5A toward a side of a plate-thickness-direction middle portion 5C of the inspection-side support 5. On the other hand, the second support plate 502 has a second taper hole portion 54 having a diameter that increases from a side of the other wall surface of the inspection-side support 5 that is positioned at an opposite side of the above-described one wall surface, that is, the opposite wall surface 5B toward the side of the plate-thickness-direction middle portion 5C of the inspection-side support 5.

Besides, when the first support plate 501 and the second support plate 502 are overlapped with each other to configure the inspection-side support 5, the first support plate 501 and the second support plate 502 are connected to each other by position adjustment so that an axial center J1 of the first taper hole portion 53 is coincident with an axial center J2 of the second taper hole portion 54. Consequently, a support hole 51 having the first taper hole portion 53 and the second taper hole portion 54 is formed in the inspection-side support 5.

An opening portion of the support hole 51 positioned at the facing wall surface 5A of the inspection-side support 5, that is, a lower-end opening portion 55 of the first taper hole portion 53, is disposed at a position facing the inspected portion 101 of the inspection target 100. In addition, a diameter D1 of the lower-end opening portion 55 of the first taper hole portion 53 is slightly larger than the outer diameter d1 of the rod-shaped body 31.

A diameter of an opening portion of the support hole 51 which is positioned at the opposite wall surface 5B of the inspection-side support 5, that is, a diameter D2 of an upper-end opening portion 56 of the second taper hole portion 54, is slightly larger than the outer diameter d1 of the rod-shaped body 31 and is smaller than the outer diameter d2 of the cylindrical body 32 of the probe 3.

For example, when the outer diameter d1 of the rod-shaped body 31 is 30 μm, and the outer diameter d2 of the cylindrical body 32 is 45 μm, the diameter D2 of the upper-end opening portion 56 is formed to be about 35 μm. Consequently, the one end portion 31a of the rod-shaped body 31 is configured to be capable of being inserted into the support hole 51. In addition, the one end portion 32a of the cylindrical body 32 is brought into contact with the opposite wall surface 5B of the inspection-side support 5 to be locked thereon and is prevented from entering the support hole 51.

A diameter of the support hole 51 that is positioned at the plate-thickness-direction middle portion 5C of the inspection-side support 5, specifically, a diameter D3 of a boundary portion positioned at a mating surface of the first support plate 501 and the second support plate 502 and between the first taper hole portion 53 and the second taper hole portion 54 is set to a value smaller than an installation interval between adjacent support holes 51 and 51, that is, an arrangement pitch P of a plurality of support holes 51 and 51.

For example, when the arrangement pitch P of the support holes 51 and 51 is 50 μm, the diameter D3 of the support hole 51 positioned at the plate-thickness-direction middle portion 5C is set to about 45 μm which is a value smaller than the arrangement pitch P. Consequently, adjacent support holes 51 and 51 are prevented from interfering with each other, and an isolation wall 57 is arranged between the support holes 51.

When the plurality of support holes 51 and 51 are formed in the inspection-side support 5, an installation error of about 4 μm may occur between the adjacent support holes 51 and 51. In order that the adjacent support holes 51 and 51 do not to interfere with each other even in this case, the diameter D3 of the support hole 51 positioned at the plate-thickness-direction middle portion 5C needs to be set to a value smaller than the arrangement pitch P of the support holes 51 and 51 by 4 μm or larger.

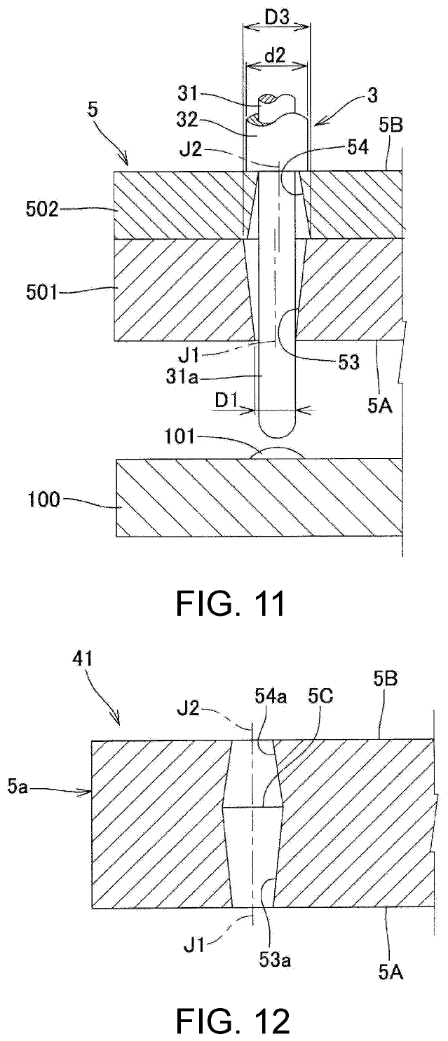

Moreover, when the first support plate 501 in which the first taper hole portion 53 is formed and the second support plate 502 in which the second taper hole portion 54 is formed are overlapped with each other, a position adjustment error may occur. Due to the position adjustment error, a positional deviation occurs between the axial center J1 of the first taper hole portion 53 and the axial center J2 of the second taper hole portion 54 in some cases (see FIG. 11). In order that even in this case the one end portion 31a of the rod-shaped body 31 is not jammed or the like when being inserted into the support hole 51, the diameter D3 of the support hole 51 positioned at the plate-thickness-direction middle portion 5C is formed larger than both the diameter D1 of the lower-end opening portion 55 and the diameter D2 of the upper-end opening portion 56.

The first support plate 501 has a thickness of about 500 μm, for example. On the other hand, the second support plate 502 has a thickness of about 320 μm, for example. In addition, a plate thickness T of the inspection-side support 5 is set to a value smaller than the projecting length 1a of the one end portion 31a of the rod-shaped body 31 which projects out of the cylindrical body 32, for example, about 80% of the projecting length 1a. That is, when the projecting length 1a of the one end portion 31a of the rod-shaped body 31 is 1,000 μm, the plate thickness T of the inspection-side support 5 is set to about 820 μm.

Consequently, when the probe 3 is supported by the support member 10, as illustrated in FIG. 2, a projecting distance 1b of the one end portion 31a of the rod-shaped body 31 which projects from the facing wall surface 5A of the inspection-side support 5 is 180 μm. In addition, by setting the plate thickness T of the inspection-side support 5 to about 80% of the projecting length 1a of the one end portion 31a as described above, a sufficient value of the plate thickness T of the inspection-side support 5 is secured. As a result, the one end portion 32a of the cylindrical body 32 which is brought into press contact with the inspection-side support 5 as described above is stably supported.

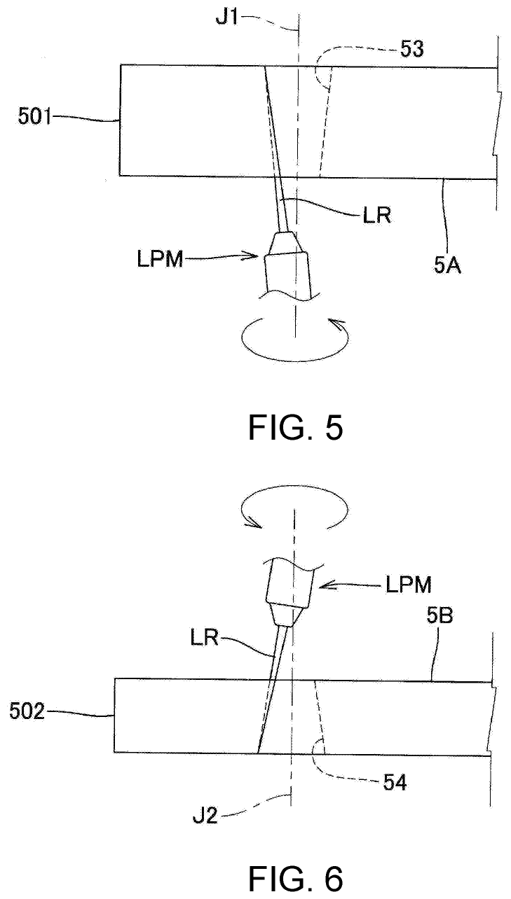

A method of manufacturing the inspection jig including the first taper hole portion 53 and the second taper hole portion 54 is described below based on FIGS. 5 and 6. The method for manufacturing the inspection jig includes a first taper hole portion forming step for forming the first taper hole portion 53 in the first support plate 501, a second taper hole portion forming step for forming the second taper hole portion 54 in the second support plate 502, and a connecting step of overlapping and connecting the first support plate 501 and the second support plate 502.

In the first taper hole portion forming step, first, as illustrated in FIG. 5, a laser processing machine LPM is disposed at a side below the first support plate 501, and an irradiation direction of a laser beam LR irradiated from the laser processing machine LPM is set to be along a circumferential wall surface of the first taper hole portion 53.

Then, while the laser processing machine LPM performs irradiation with the laser beam LR toward a lower surface (facing wall surface 5A) of the first support plate 501, the laser processing machine LPM is turned around a center which is the axial center J1 of the first taper hole portion 53 for one or more times. Consequently, the first taper hole portion 53 having a diameter that increases from the side of the facing wall surface 5A toward the side of the plate-thickness-direction middle portion 5C of the inspection-side support 5 is formed in the first support plate 501 (see FIG. 4).

In the second taper hole portion forming step, as illustrated in FIG. 6, the laser processing machine LPM is disposed at a side above the second support plate 502, and an irradiation direction of a laser beam LR irradiated from the laser processing machine LPM is set to be along a circumferential wall surface of the second taper hole portion 54.

Then, similar to the method for forming the first taper hole portion 53, while the laser processing machine LPM performs irradiation with the laser beam LR toward an upper surface (opposite wall surface 5B) of the second support plate 502, the laser processing machine LPM is turned around a center which is the axial center J2 of the support hole 51. Consequently, the second taper hole portion 54 having a diameter that increases from the side of the opposite wall surface 5B toward the side of the plate-thickness-direction middle portion 5C of the inspection-side support 5 is formed in the second support plate 502.

Subsequently, in the connecting step, after position adjustment is performed so that the axial center J1 of the first taper hole portion 53 is coincident with the axial center J2 of the second taper hole portion 54, the first support plate 501 and the second support plate 502 are overlapped to be connected, and thereby the inspection-side support 5 is configured as illustrated in FIG. 4.

Moreover, the method for forming the first taper hole portion 53 and the second taper hole portion 54 is not limited to the processing method in which the above-described laser processing machine LPM is used. For example, a taper reamer or the like may be used to form the first taper hole portion 53 in the first support plate 501 and form the second taper hole portion 54 in the second support plate 502. In addition, when a 3D printer is used to form the inspection-side support 5, the first taper hole portion 53 and the second taper hole portion 54 can be formed simultaneously.

In the above-described embodiment, the plate thickness of the first support plate 501 is set to 500 μm, and the plate thickness of the second support plate 502 is set to 320 μm; however, the plate thickness is not limited thereto. The plate thicknesses of the first support plate 501 and the second support plate 502 may be the same value, for example, 400 μm.

The electrode-side support 6 that configures the support member 10 is configured of a plate-shaped body installed to face an electrode plate 9 positioned at the upper portion in FIG. 2. A probe supporting hole 61 configured of a straight hole penetrating the electrode-side support 6 in a plate-thickness direction is formed in the electrode-side support 6. The probe supporting hole 61 has an aperture diameter that is set to a value larger than the outer diameter d2 of the cylindrical body 32. Besides, a rear end portion of the probe 3, specifically, the other end portion 32b of the cylindrical body 32, is inserted into the probe supporting hole 61 to be supported therein.

Moreover, a conductive wire 90 is arranged at the electrode plate 9, and an end surface of the conductive wire configures an electrode 91 with which the rear end portion of the probe 3 is brought into contact.

The middle portion support 7 is configured of a plate-shaped body disposed between the inspection-side support 5 and the electrode-side support 6. A middle portion supporting hole 71 configured of a straight hole penetrating the middle portion support 7 in the plate-thickness direction is formed in the middle portion support 7. The middle portion supporting hole 71 has an aperture diameter that is set to a value larger than the outer diameter d2 of the cylindrical body 32. Besides, a portion of the cylindrical body 32 in the vicinity of an axial-direction middle portion is inserted into the middle portion supporting hole 71 to be supported therein.

As illustrated in FIG. 2, a distance L1 from the facing wall surface 5A of the inspection-side support 5 to an outer wall surface 60 of the electrode-side support 6 is set to be shorter than an entire length of the probe 3 in a state that a load is not applied to the probe. As a result, when the probe 3 is supported by the support member 10, the one end portion 31a of the rod-shaped body 31 comes into a state of projecting out of the support member 10 by the constant projecting distance 1b.

In addition, a distance L2 from the opposite wall surface 5B of the inspection-side support 5 to the outer wall surface 60 of the electrode-side support 6 is set to be shorter than an entire length of the cylindrical body 32 in a state that a load is not applied to the cylindrical body. As a result, when the probe 3 is supported by the support member 10, the other end portion 32b of the cylindrical body 32 comes into a state of projecting out of the outer wall surface 60 of the electrode-side support 6 by a constant distance.

When the inspection jig 4 having the above-described configuration is assembled, the one end portion 31a of the rod-shaped body 31 is inserted into the middle portion supporting hole 71 from the inside of the probe supporting hole 61, and then inserted into the support hole 51 of the inspection-side support 5. Consequently, the other end portion 32b and the portion in the vicinity of the axial-direction middle portion of the cylindrical body 32 are supported by the electrode-side support 6 and the middle portion support 7, respectively. In addition, the one end portion 31a of the rod-shaped body 31 is supported by the inspection-side support 5.

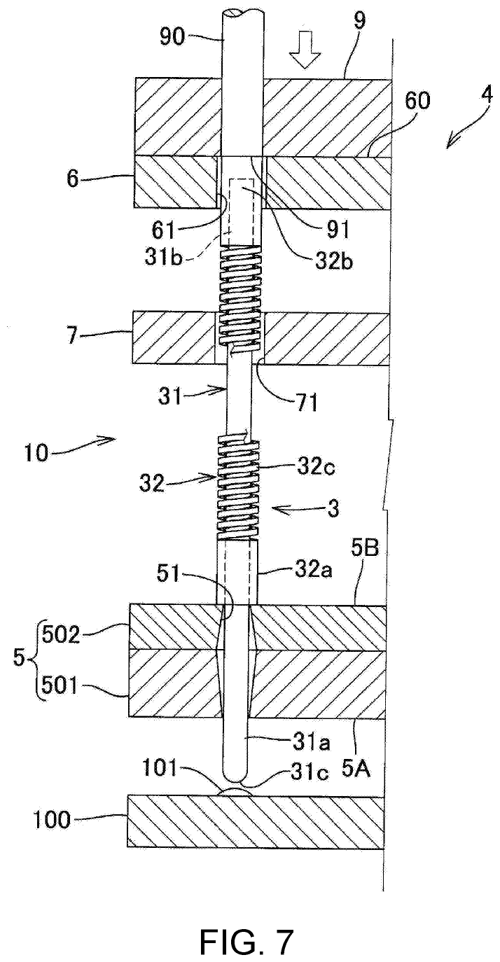

Subsequently, after the electrode plate 9 and the inspection jig 4 are positioned in a horizontal direction, as illustrated in FIG. 7, the electrode plate 9 is brought into contact with and connected to the outer wall surface 60 of the electrode-side support 6, and thereby the spring portion 32c of the cylindrical body 32 is compressed to be elastically deformed. As a result, the other end portion 32b of the cylindrical body 32 is brought into press contact with the electrode 91 with a predetermined pressing force so as to achieve conductive connection therebetween.

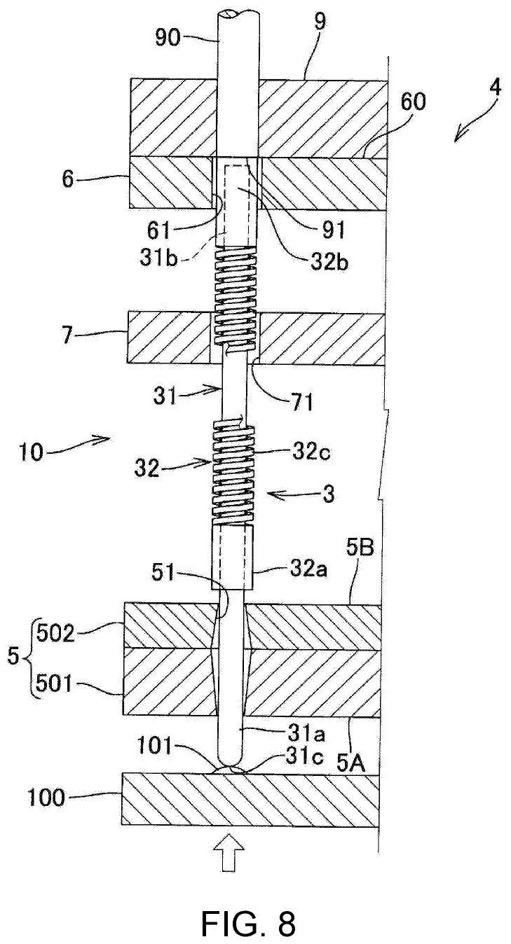

In order to inspect the inspection target 100 using the above-described inspection jig 4, after the inspection target 100 and the inspection jig 4 are positioned in the horizontal direction, a driving mechanism (not illustrated) performs lifting/lowering drive of the inspection jig 4. Then, as illustrated in FIG. 8, one end portion of the probe 3, specifically, the one end portion 31a of the rod-shaped body 31 is brought into press contact with the inspected portion 101 of the inspection target 100 so as to achieve conductive connection therebetween. In addition, the spring portion 32c of the cylindrical body 32 is further compressed and elastically deformed from the state in FIG. 7, and thereby the one end portion 31a of the rod-shaped body 31 is brought into press contact with the inspected portion 101 with a sufficient pressing force.

In this manner, the one end portion of the probe 3 which is configured of the one end portion 31a of the rod-shaped body 31 is conductively connected to the inspected portion 101 of the inspection target 100, and the rear end portion of the probe 3 which is configured of the other end portion 32b of the cylindrical body 32 is conductively connected to the electrode 91. In this state, an electric signal is transmitted to the rear end portion of the probe 3, and thereby inspection of the inspection target 100 is performed.

As illustrated in FIG. 4, the inspection jig 4 according to a first embodiment of the disclosure includes the first support that is prearranged to be disposed to face the inspection target 100, specifically, the inspection-side support 5 having the facing wall surface 5A facing the inspection target 100 and the opposite wall surface 5B positioned at the opposite side of the facing wall surface 5A. The inspection-side support 5 includes the first taper hole portion 53 having a diameter that increases from the facing wall surface 5A toward the side of the plate-thickness-direction middle portion 5C of the inspection-side support 5 and the second taper hole portion 54 having a diameter that increases from the side of the opposite wall surface 5B toward the side of the plate-thickness-direction middle portion 5C of the inspection-side support 5.

In addition, the diameter D2 of the upper-end opening portion 56 of the support hole 51 which is positioned at the side of the opposite wall surface 5B of the inspection-side support 5 is set to a value larger than the outer diameter d1 of the rod-shaped body 31 and smaller than the outer diameter d2 of the cylindrical body 32 (see FIG. 4). Further, the diameter D1 of the lower-end opening portion 55 of the support hole 51 which is positioned at the side of the facing wall surface 5A of the inspection-side support 5 is set to a value slightly larger than the outer diameter d1 of the rod-shaped body 31.

Hence, when the one end portion 31a of the rod-shaped body 31 is inserted into the support hole 51 from the upper-end opening portion 56 to be supported by the inspection-side support 5, the one end portion 31a of the rod-shaped body 31 is appropriately restrained by the lower-end opening portion 55 or the like of the support hole 51. Consequently, the one end portion of the probe 3 can be accurately aligned with the inspected portion 101 of the inspection target 100.

The rod-shaped body 31 of the probe 3 is formed to have the outer diameter d1 set to a very small value of about 30 μm, for example. In addition, the plate thickness T of the inspection-side support 5 is set to a large value so that the one end portion 32a of the cylindrical body 32 which is brought into press contact with the inspection-side support 5 can be stably supported. Therefore, in a case that the plate thickness T of the inspection-side support 5 is set to, for example, a value 30 times or larger than the outer diameter d1 of the rod-shaped body 31, when a drill having a fine diameter is used to perform hole processing of forming a hole having a predetermined length on the inspection-side support 5 for once, the drill is likely to be bent or the like.

Moreover, an increase in a hole diameter is considered so as to prevent the drill from being bent or the like; however, in this case, it is difficult to stably support the one end portion of the probe 3. Hence, the probe 3 is likely to wobble, and it is difficult to accurately align the one end portion of the probe 3 with the inspected portion 101 of the inspection target 100.

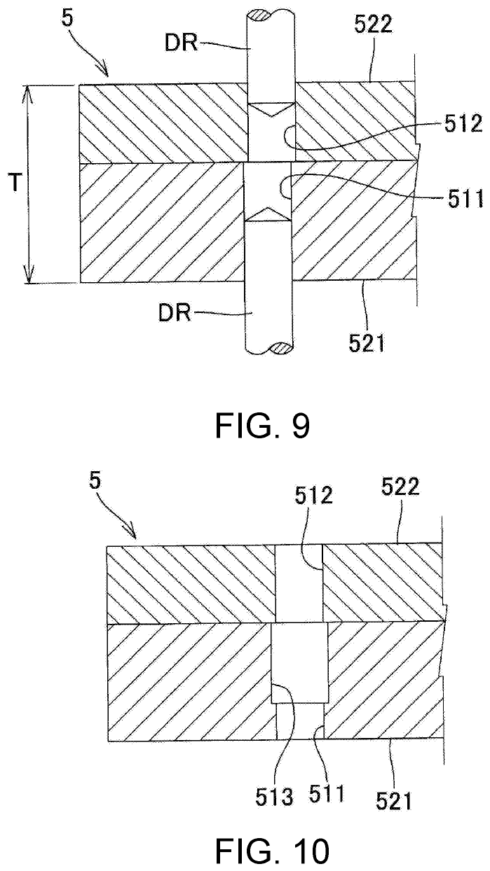

On the other hand, in a first reference example illustrated in FIG. 9, a lower drill hole 511 and an upper drill hole 512 respectively configured of a straight hole are separately arranged in a lower support plate 521 and an upper support plate 522 which configure the support 5. According to this configuration, even when the plate thickness T of the support 5 is large, the lower drill hole 511 and the upper drill hole 512 having a fine diameter can be formed while a drill DR is prevented from being bent or the like.

However, in a case of a configuration as illustrated in FIG. 9, a positional deviation is likely to occur between the lower drill hole 511 formed in the lower support plate 521 and the upper drill hole 512 formed in the upper support plate 522. Therefore, in the first reference example illustrated in FIG. 9, when one end portion of the probe is inserted into the lower drill hole 511 and the upper drill hole 512, the probe is likely to be jammed at a portion of the above-described positional deviation, or abnormal sliding of the probe is likely to occur.

In contrast, in the first embodiment of the disclosure, as illustrated in FIG. 4, the first taper hole portion 53 having a diameter that increases from the facing wall surface 5A toward the side of the plate-thickness-direction middle portion 5C and the second taper hole portion 54 having a diameter that increases from the side of the opposite wall surface 5B toward the side of the plate-thickness-direction middle portion 5C are arranged in the inspection-side support 5. As a result, the diameter D3 of the support hole of the rod-shaped body positioned at the plate-thickness-direction middle portion 5C is set to a value larger than both the diameter D1 of the lower-end opening portion 55 positioned at the facing wall surface 5A and the diameter D2 of the upper-end opening portion 56 positioned at the opposite wall surface 5B.

Hence, even when a certain degree of positional deviation occurs between the first taper hole portion 53 and the second taper hole portion 54 during the overlapping of the first support plate 501 in which the first taper hole portion 53 is formed and the second support plate 502 in which the second taper hole portion 54 is formed, the probe 3 is unlikely to be jammed or the like at the portion of the positional deviation. Therefore, the one end portion 31a of the rod-shaped body 31 can be smoothly inserted into the first taper hole portion 53 from the second taper hole portion 54.

Additionally, since the diameter D1 of the lower-end opening portion 55 positioned at the facing wall surface 5A is set to a value smaller than the diameter D3 of the support hole 51 positioned at the plate-thickness-direction middle portion 5C, the one end portion of the probe 3 which is configured of the one end portion 31a of the rod-shaped body 31 can be appropriately restrained by the lower-end opening portion 55 to effectively prevent the probe 3 from wobbling.

Furthermore, when a configuration is employed in which a middle drill hole 513 having a large diameter and the lower drill hole 511 having a small diameter are arranged in the lower support plate 521 and the upper drill hole 512 having a small diameter is arranged in the support plate 522 to prevent the probe from being jammed, as will be described in a second reference example illustrated in FIG. 10, it is necessary to perform drill-hole processing three times. In contrast, in the inspection jig 4 according to the first embodiment of the disclosure, the number of times of hole processing performed using a drill or the like can be reduced. Therefore, productivity of the inspection jig 4 can be effectively improved.

In the above-described first embodiment, as illustrated in FIG. 4 and the like, the probe 3 is configured to have the rod-shaped body 31 configured of the conductive member and the cylindrical body 32 configured of the conductive member externally fitted on the rod-shaped body 31, the helical spring portion 32c being arranged in the cylindrical body 32. Besides, the diameter D3 of the lower-end opening portion 55 of the support hole 51 which is positioned at the side of the facing wall surface 5A is set to a value slightly larger than the outer diameter d1 of the rod-shaped body 31, and thereby the one end portion 31a of the rod-shaped body 31 is restrained by the lower-end opening portion 55. Consequently, the one end portion of the probe 3 and the inspected portion 101 of the inspection target 100 can be accurately aligned.

In addition, the diameter D2 of the upper-end opening portion 56 positioned at the side of the opposite wall surface 5B is set to a value smaller than the outer diameter d2 of the cylindrical body 32, and thus the one end portion 32a of the cylindrical body 32 is brought into press contact with and locked on the opposite wall surface 5B of the inspection-side support 5. As a result, a large press-contact force from the cylindrical body 32 is applied to the inspection-side support 5. However, as described above, the plate thickness T of the inspection-side support 5 can be set to a thickness by which sufficient strength can be obtained, and thus the one end portion 32a of the cylindrical body 32 can be stably supported.

Moreover, in the above-described embodiment, an example is described in which the support hole 51 including the first taper hole portion 53 and the second taper hole portion 54 is formed in the first support configured of the inspection-side support 5 which is prearranged to be disposed to face the inspection target 100. However, the disclosure is not limited thereto and may employ a configuration in which another support that supports the probe 3, for example, the second support configured of the electrode-side support 6 or the middle portion support 7, has the first taper hole portion or the like having a diameter that increases from the side of the one wall surface toward the side of the plate-thickness-direction middle portion of the second support.

In addition, instead of the above-described first embodiment which includes the probe 3 having the rod-shaped body 31 configured of a conductive member and the cylindrical body 32 configured of a conductive member into which the rod-shaped body 31 is inserted, the disclosure can be also applied to the inspection jig 4 including a needle type probe that is formed into a needle shape having a predetermined length by a conductive member and applied to the inspection apparatus 1 including the inspection jig 4.

Moreover, an inspection jig 41 according to a variation example of the first embodiment illustrated in FIG. 12 includes an inspection-side support 5a configured of a single plate. Besides, the first taper hole portion 53 is arranged in a part at a side of the facing wall surface 5A of the inspection-side support 5a, and the second taper hole portion 54 is arranged in a part at a side of the opposite wall surface 5B of the inspection-side support 5a.

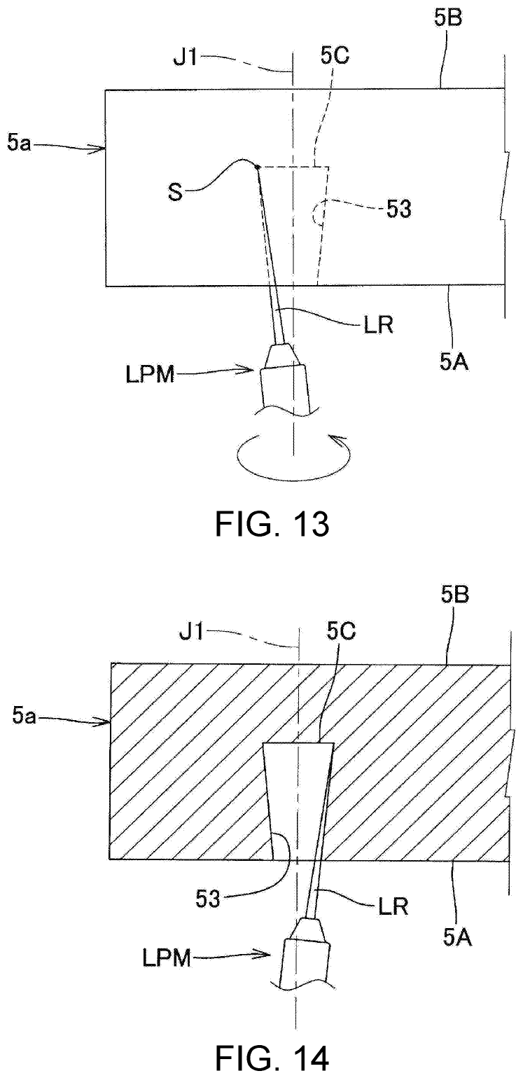

As illustrated in FIG. 13, in order to form the first taper hole portion 53, the laser processing machine LPM is disposed at a side below the facing wall surface 5A, and an irradiation direction of the laser beam LR irradiated from the laser processing machine LPM is set to be along a circumferential wall surface of the first taper hole portion 53. In addition, a focus S of the laser beam LR is set to be coincident with the plate-thickness-direction middle portion 5C of the inspection-side support 5.

Then, while the laser processing machine LPM performs irradiation with the laser beam LR toward the facing wall surface 5A of the inspection-side support 5a, the laser processing machine LPM is turned around the centre which is the axial center J1 of the first taper hole portion 53 for one or more times. Consequently, as illustrated in FIG. 14, the first taper hole portion 53 having a diameter that increases from the side of the facing wall surface 5A to the side of the plate-thickness-direction middle portion 5C of the inspection-side support 5a is formed.

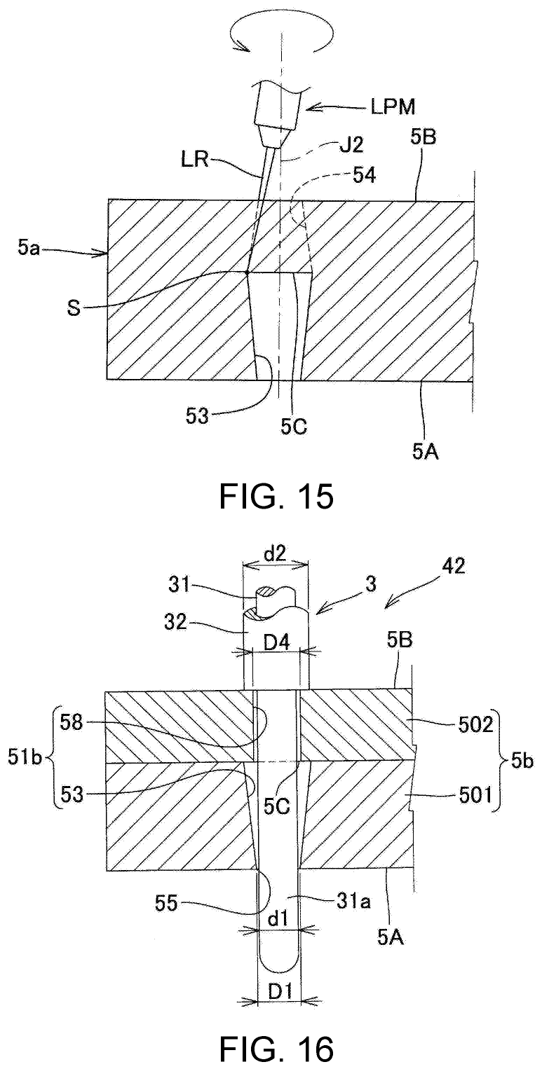

Subsequently, as illustrated in FIG. 15, the laser processing machine LPM is disposed at a side above the opposite wall surface 5B, and an irradiation direction of the laser beam LR irradiated from the laser processing machine LPM is set to be along a circumferential wall surface of the second taper hole portion 54. In addition, a focus S of the laser beam LR is set to be coincident with the plate-thickness-direction middle portion 5C of the inspection-side support 5a.

Then, similar to the method for forming the first taper hole portion 53, while the laser processing machine LPM performs irradiation with the laser beam LR toward the opposite wall surface 5B of the inspection-side support 5a, the laser processing machine LPM is turned around the center which is the axial center J2 of the second taper hole portion 54. Consequently, as illustrated in FIG. 12, the second taper hole portion 54 having a diameter that increases from the side of the opposite wall surface 5B to the side of the plate-thickness-direction middle portion 5C of the inspection-side support 5a is formed.

Moreover, in the above-described first embodiment, as illustrated in FIG. 4, FIG. 11, and the like, the first taper hole portion 53 and the second taper hole portion 54 are individually formed in the first support plate 501 and the second support plate 502, respectively. Therefore, when the first support plate 501 and the second support plate 502 are aligned to be overlapped, an alignment error may occur. In contrast, in the inspection jig 41 of the variation example illustrated in FIG. 12, both a first taper hole portion 53a and a second taper hole portion 54a are arranged in the inspection-side support 5a configured of a single plate, and thus deviation between the axial center J1 of the first taper hole portion 53a and the axial center J2 of the second taper hole portion 54a can be effectively reduced.

In addition, a 3D printer may be used to form the above-described inspection-side support 5a. In this case, the first taper hole portion 53 and the second taper hole portion 54 can be continuously formed in the inspection-side support 5a.

Moreover, instead of the above-described first embodiment in which both the first taper hole portion 53 and the second taper hole portion 54 are formed in the inspection-side support 5 or 5a, a configuration may be employed in which the first taper hole portion 53 is arranged only at one side of the facing wall surface 5A or the opposite wall surface 5B, as illustrated in a second embodiment or a third embodiment described below.

### Second Embodiment

FIG. 16 illustrates the second embodiment of an inspection jig 42 according to the disclosure. The inspection jig 42 includes a first taper hole portion 53 having a diameter that increases from a side of the facing wall surface 5A toward a side of the plate-thickness-direction middle portion 5C of an inspection-side support 5b and a straight hole portion 58 that is extended with a uniform aperture diameter D4 from a side of the opposite wall surface 5B toward the side of the plate-thickness-direction middle portion 5C of the inspection-side support 5b. Besides, a support hole 51b that supports the one end portion 31a of the rod-shaped body 31 is configured of the first taper hole portion 53 and the straight hole portion 58.

The diameter D1 of the first taper hole portion 53 positioned at the side of the facing wall surface 5A of the inspection-side support 5b is set to a value slightly larger than the outer diameter d1 of the rod-shaped body 31. In addition, an aperture diameter D4 of the straight hole portion 58 positioned at the side of the opposite wall surface 5B of the inspection-side support 5b is set to a value slightly larger than the outer diameter d1 of the rod-shaped body 31 and smaller than the outer diameter d2 of the cylindrical body 32 of the probe 3.

In this configuration, the cylindrical body 32 of the probe 3 can also be stably supported at the opposite wall surface 5B of the inspection-side support 5b by setting the plate thickness of the inspection-side support 5b configured of the first support plate 501 and the second support plate 502 to a sufficiently large value. Besides, even in a case that positional deviation occurs between the first taper hole portion 53 at the side of the facing wall surface 5A and the straight hole portion 58 at the opposite wall surface 5B, jamming or the like is unlikely to occur at the portion of the above-described positional deviation when the one end portion 31a of the rod-shaped body 31 is inserted into the first taper hole portion 53 from the straight hole portion 58.

Additionally, the diameter D1 of a lower end portion of the first taper hole portion 53 positioned at the side of the facing wall surface 5A is smaller than a diameter of an upper end portion of the first taper hole portion 53 positioned at the side of the plate-thickness-direction middle portion 5C. Therefore, the one end portion 31a of the rod-shaped body 31 is effectively restrained by the lower-end opening portion 55 of the first taper hole portion 53 and wobbling of the probe 3 is inhibited. Hence, the one end portion of the probe 3 can be accurately aligned with the inspected portion of the inspection target.

In the above-described second embodiment, similar to the inspection jig 4 according to the first embodiment illustrated in FIG. 4 and the like, the inspection-side support 5b is also configured to have the first support plate 501 that is positioned at the side of the facing wall surface 5A and the second support plate 502 that is positioned at the side of the opposite wall surface 5B. According to this configuration, the first taper hole portion 53 can be easily formed in the first support plate 501 using a taper reamer, a laser processing machine, or the like. In addition, the straight hole portion 58 can be easily formed in the second support plate 502 using a straight drill, the laser processing machine, or the like.

Moreover, in the inspection jig 42 according to the second embodiment of the disclosure, the inspection-side support 5 configured of a single plate may also be formed by a 3D printer. In this case, when the inspection-side support 5 is formed by the 3D printer, the first taper hole portion 53 and the straight hole portion 58 can be continuously formed.

### Third Embodiment

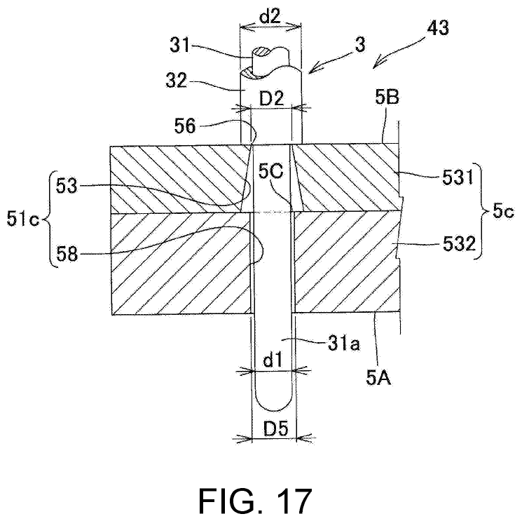

FIG. 17 illustrates an inspection jig 43 according to a third embodiment of the disclosure. In the inspection jig 43, an inspection-side support 5c is configured by a first support plate 531 disposed at a side of the opposite wall surface 5B and a second support plate 532 disposed at a side of the facing wall surface 5A.

Besides, a first taper hole portion 53 having a diameter that increases from the opposite wall surface 5B toward the side of a plate-thickness-direction middle portion 5C of the inspection-side support 5c is formed in the first support plate 531. In addition, a straight hole portion 58 that is extended with a uniform aperture diameter from the side of the facing wall surface 5A toward the side of the plate-thickness-direction middle portion 5C of the inspection-side support 5c is formed in the second support plate 532. Besides, a support hole 51c that supports the one end portion 31a of the rod-shaped body 31 is formed by the first taper hole portion 53 and the straight hole portion 58. In addition, an aperture diameter D5 of the straight hole portion 58 is set to a value larger than the outer diameter d1 of the rod-shaped body 31.

In this configuration, the plate thickness of the inspection-side support 5c can also be set to a sufficiently large value to stably support the cylindrical body 32 of the probe 3 by the inspection-side support 5c. Besides, the aperture diameter D5 of the straight hole portion 58 is set to a value sufficiently larger than the outer diameter d1 of the rod-shaped body 31. Consequently, even when positional deviation occurs between the first taper hole portion 53 and the straight hole portion 58, the one end portion 31a of the rod-shaped body 31 can be smoothly inserted into the straight hole portion 58 from the first taper hole portion 53, without occurrence of jamming or the like at the portion of the positional deviation.

Additionally, the diameter D2 of the upper-end opening portion 56 of the first taper hole portion 53 positioned at the side of the opposite wall surface 5B of the inspection-side support 5c is set to be smaller than the diameter of the lower end portion of the first taper hole portion 53 positioned at the side of the plate-thickness-direction middle portion 5C of the inspection-side support 5c. Therefore, the one end portion 31a of the rod-shaped body 31 is restrained by the upper-end opening portion 56 of the first taper hole portion 53 and wobbling of the probe 3 is prevented. Hence, the one end portion of the probe 3 can be aligned with the inspected portion of the inspection target.

In addition, in the above-described third embodiment, the inspection-side support 5c is configured to have the first support plate 531 that is positioned at the side of the opposite wall surface 5B and the second support plate 532 that is positioned at the side of the facing wall surface 5A. According to this configuration, the first taper hole portion 53 can be easily formed in the first support plate 531 using a taper reamer, a laser processing machine, or the like. In addition, the straight hole portion 58 can be easily formed in the second support plate 532 using a straight drill, a laser processing machine, or the like.

In the inspection jig 43 according to the above-described third embodiment, the inspection-side support 5 configured of a single plate can also be formed by a 3D printer.

As described above, the inspection jig according to an example of the disclosure includes the rod-shaped probe in which the one end portion is brought into press contact with the inspection target and the plate-shaped first support having the support hole which supports the probe. The support hole has the first taper hole portion having a diameter that increases from the side of the one wall surface of the first support toward the side of the plate-thickness-direction middle portion of the first support.

According to this configuration, even when the plate thickness of the first support is large, the probe can be stably supported without cumbersome hole processing work. Therefore, the inspection jig capable of accurately aligning the probe with the inspected portion or the like of the inspection target can be efficiently produced.

In addition, the support hole may be configured to further include a second taper hole portion having a diameter that increases from the side of the other wall surface positioned at the opposite side of the one wall surface toward the side of the plate-thickness-direction middle portion.

According to this configuration, even in a case that a certain degree of positional deviation occurs between the first taper hole portion at the side of the one wall surface and the second taper hole portion at the side of the other wall surface when the first taper hole portion and the second taper hole portion are separately formed, the occurrence of jamming or the like at the portion of the above-described positional deviation can be effectively prevented when one end portion of the probe is inserted into the first taper hole portion from the second taper hole portion. Furthermore, the probe can be restrained by the opening portion of the first taper hole portion positioned at the side of the one wall surface to prevent wobbling of the probe, and thus the probe can be accurately aligned with the inspected portion or the like of the inspection target.

In addition, the support hole may be configured to further include a straight hole portion which is extended with a uniform aperture diameter from the side of the other wall surface at the opposite side of the one wall surface toward the side of the plate-thickness-direction middle portion.

According to this configuration, the plate thickness of the first support is set to a sufficiently large value, and thereby the probe can be stably supported. Besides, even when positional deviation occurs between the above-described taper hole portion and the straight hole portion, the probe can be smoothly inserted into the support hole without occurrence of jamming or the like at the portion of the positional deviation. Furthermore, the probe can be restrained by the opening portion of the first taper hole portion positioned at the side of the one wall surface of the first support to prevent wobbling of the probe, and thus the probe can be accurately aligned with the inspected portion or the like of the inspection target.

In addition, in this configuration, the first support may have the first support plate which is positioned at the side of the one wall surface and the second support plate which is positioned at the side of the other wall surface, and the first taper hole portion may be arranged in the first support plate.

According to this configuration, the first taper hole portion can be easily formed in the first support plate using a taper reamer or the like. Then, the first support plate and the second support plate are overlapped to be connected to each other, and thereby the support hole including the first taper hole portion is arranged at the first support.

In addition, the inspection jig may further include a second support that supports the probe, and the first support is prearranged to be disposed to face the inspection target.

According to this configuration, even when the plate thickness of the first support is large, the one end portion of the probe close to the inspection target can be stably supported by the support without cumbersome hole processing work. Therefore, the one end portion of the probe can be accurately aligned with the inspected portion of the inspection target.

In addition, the probe may have a rod-shaped body configured of a conductive member and having one end portion supported by the support hole, and a cylindrical body configured of a conductive member and externally fitted on the rod-shaped body, a helical spring portion is arranged in the cylindrical body, and the diameter of the first taper hole portion positioned at the side of the one wall surface is larger than the outer diameter of the rod-shaped body and smaller than the outer diameter of the cylindrical body.

According to this configuration, the road-shaped body of the probe can be restrained by the opening portion of the first taper hole portion positioned at the side of the one wall surface to prevent wobbling of the probe, and thus the one end portion of the rod-shaped body can be accurately aligned with the inspected portion of the inspection target.

The method for manufacturing inspection jig according to an example of the disclosure includes the first taper hole portion forming step for forming the first taper hole portion in the first support plate and the connecting step for overlapping and connecting the first support plate and the second support plate.

According to this configuration, the first taper hole portion can be easily formed in the first support plate using a taper reamer or the like. Besides, the first support plate and the second support plate are overlapped to be connected to each other, and thereby the support hole including the first taper hole portion is arranged in the first support.

In addition, in the first taper hole portion forming step, the laser processing machine may be disposed at the side of the one wall surface, the irradiation direction of the laser beam irradiated from the laser processing machine is set to be along the circumferential wall surface of the first taper hole portion, and then the laser processing machine is turned around the center which is the axial center of the first taper hole portion while the first support plate is irradiated with the laser beam from the laser processing machine, thereby forming the first taper hole portion.

According to this configuration, the first taper hole portion can be easily and appropriately formed in the first support plate using the laser processing machine.

In addition, the inspection apparatus according to an example of the disclosure includes the above-described inspection jig and the inspection part that is electrically connected to the rear end portion of the probe and transmits the electric signal to the rear end portion of the probe so as to inspect the inspection target.

According to this configuration, even when the plate thickness of the first support is large, the probe can be stably supported without cumbersome hole processing work, and thereby the inspection target can be appropriately inspected in a state that the one end portion of the probe is accurately aligned with the inspected portion of the inspection target.

What is claimed is:

1. An inspection jig comprising:
a rod-shaped probe in which one end portion is brought into press contact with an inspection target; and
a plate-shaped first support having a support hole which supports the probe;
wherein the support hole comprises a first taper hole portion having a diameter that increases from a side of one wall surface of the first support toward a side of a plate-thickness-direction middle portion of the first support.

2. The inspection jig according to claim 1,
wherein the support hole further comprises a second taper hole portion having a diameter that increases from a side of another wall surface positioned at an opposite side of the one wall surface toward the side of the plate-thickness-direction middle portion.

3. The inspection jig according to claim 1,
wherein the support hole further comprises a straight hole portion which is extended with a uniform aperture diameter from a side of another wall surface positioned at an opposite side of the one wall surface toward the side of the plate-thickness-direction middle portion.

4. The inspection jig according to claim 2,
wherein the first support has a first support plate which is positioned at the side of the one wall surface and a second support plate which is positioned at the side of the another wall surface, and
wherein the first taper hole portion is arranged in the first support plate.

5. The inspection jig according to claim 1, further comprising a second support that supports the probe,
wherein the first support is prearranged to be disposed to face the inspection target.

6. The inspection jig according to claim 5,
wherein the probe has a rod-shaped body configured of a conductive member and a cylindrical body configured of a conductive member into which the rod-shaped body is inserted,
wherein the cylindrical body has a helical spring portion, and
wherein a diameter of the first taper hole portion positioned at the side of the one wall surface is larger than an outer diameter of the rod-shaped body and smaller than an outer diameter of the cylindrical body.

7. The inspection jig according to claim 3,
wherein the first support has a first support plate which is positioned at the side of the one wall surface and a second support plate which is positioned at the side of the another wall surface, and
wherein the first taper hole portion is arranged in the first support plate.

8. The inspection jig according to claim 2, further comprising a second support that supports the probe,
wherein the first support is prearranged to be disposed to face the inspection target.

9. The inspection jig according to claim 3, further comprising a second support that supports the probe,
wherein the first support is prearranged to be disposed to face the inspection target.

10. The inspection jig according to claim 4, further comprising a second support that supports the probe,
wherein the first support is prearranged to be disposed to face the inspection target.

11. The inspection jig according to claim 8,
wherein the probe has a rod-shaped body configured of a conductive member and a cylindrical body configured of a conductive member into which the rod-shaped body is inserted,
wherein the cylindrical body has a helical spring portion, and
wherein a diameter of the first taper hole portion positioned at the side of the one wall surface is larger than an outer diameter of the rod-shaped body and smaller than an outer diameter of the cylindrical body.

12. The inspection jig according to claim 9,
wherein the probe has a rod-shaped body configured of a conductive member and a cylindrical body configured of a conductive member into which the rod-shaped body is inserted,
wherein the cylindrical body has a helical spring portion, and
wherein a diameter of the first taper hole portion positioned at the side of the one wall surface is larger than an outer diameter of the rod-shaped body and smaller than an outer diameter of the cylindrical body.

13. The inspection jig according to claim 10,
wherein the probe has a rod-shaped body configured of a conductive member and a cylindrical body configured of a conductive member into which the rod-shaped body is inserted,
wherein the cylindrical body has a helical spring portion, and
wherein a diameter of the first taper hole portion positioned at the side of the one wall surface is larger than an outer diameter of the rod-shaped body and smaller than an outer diameter of the cylindrical body.

14. A method for manufacturing the inspection jig according to claim 4, the method comprising:
a first taper hole portion forming step for forming the first taper hole portion in the first support plate; and
a connecting step for overlapping and connecting the first support plate and the second support plate.

15. The method for manufacturing inspection jig according to claim 14,
wherein, in the first taper hole portion forming step, a laser processing machine is disposed at the side of the one wall surface, an irradiation direction of a laser beam irradiated from the laser processing machine is set to be along a circumferential wall surface of the first taper hole portion, and then the laser processing machine is turned around a center which is an axial center of the first taper hole portion while the first support plate is irradiated with the laser beam from the laser processing machine, thereby forming the first taper hole portion.

16. An inspection apparatus comprising the inspection jig according to claim 1; and an inspection part that is electrically connected to a rear end portion of the probe and transmits an electric signal to the rear end portion of the probe so as to inspect an inspection target.

17. An inspection apparatus comprising the inspection jig according to claim 2; and an inspection part that is electrically connected to a rear end portion of the probe and transmits an electric signal to the rear end portion of the probe so as to inspect an inspection target.

18. An inspection apparatus comprising the inspection jig according to claim 3; and an inspection part that is electrically connected to a rear end portion of the probe and transmits an electric signal to the rear end portion of the probe so as to inspect an inspection target.

19. An inspection apparatus comprising the inspection jig according to claim 4; and an inspection part that is electrically connected to a rear end portion of the probe and transmits an electric signal to the rear end portion of the probe so as to inspect an inspection target.
